(19) United States
(12) Patent Application Publication
(10) Pub. No.: US 2011/0211392 A1
(43) Pub. Date: Sep. 1, 2011

(54) CELL STRING OF A MEMORY CELL ARRAY AND METHOD OF ERASING THE SAME

(75) Inventors: Jae-Ho Kim, Seoul (KR); Jae-Kwan Park, Suwon-si (KR); Byung-Jun Hwang, Seoul (KR); Sung-Bo Shim, Gwangmyeong-si (KR); Hye-Young Kwon, Suwon-si (KR)

(73) Assignee: SAMSUNG ELECTRONICS CO., LTD., Suwon-si (KR)

(21) Appl. No.: 12/961,647

(22) Filed: Dec. 7, 2010

(30) Foreign Application Priority Data
Feb. 26, 2010 (KR) 10-2010-0017577

(51) Int. Cl. G11C 16/06; H01L 29/788; H01L 29/792; G11C 16/04

(52) U.S. Cl. 365/185.2; 257/315; 257/324; 365/185.18; 365/185.33; 257/E29.3; 257/E29.309

(57) ABSTRACT

A cell string included in a memory cell array of a nonvolatile memory device includes a plurality of memory cells, a string select transistor, and a ground select transistor. The plurality of memory cells are connected in series. The string select transistor is connected between a bitline and the plurality of memory cells, and has a structure substantially the same as a structure of each memory cell. The ground select transistor is connected between the plurality of memory cells and a common source line, and has a structure substantially the same as the structure of each memory cell.

### CROSS-REFERENCE TO RELATED APPLICATION(S)

A claim of priority under 35 USC §119 is made to Korean Patent Application No. 2010-0017577, filed on Feb. 26, 2010, in the Korean Intellectual Property Office (KIPO), the contents of which are incorporated herein in its entirety by reference.

### BACKGROUND

The inventive concept relates generally to semiconductor memory devices. More particularly, the inventive concept relates to a cell string included in a memory cell array of a flash memory device, and to a method of erasing a cell string included in a memory cell array of a flash memory device.

A flash memory device is a type of nonvolatile memory device that can continuously maintain stored data even if power is not supplied. The flash memory device is generally classified into a NOR flash memory device including memory cells connected in parallel and a NAND flash memory device including memory cells connected in series. The NAND flash memory device has an advantage of high density compared to the NOR flash memory device.

A memory cell array of the NAND flash memory device includes a plurality of cell strings connected between bitlines and a common source line. Each cell string includes a string select transistor, a plurality of memory cells and a ground select transistor that are connected in series.

In a conventional NAND flash memory device, a structure of the string select transistor or the ground select transistor is different from a structure of each memory cell. Accordingly, an additional process may be required to form the string select transistor or the ground select transistor. For example, a butting process is required to form a contact between a control gate and a floating gate in the string select transistor or the ground select transistor. Further, the string select transistor or the ground select transistor must have a size larger than that of each memory cell because of the butting process, thereby reducing the cell density. Such a deterioration of the cell density intensifies as a design rule decreases.

### SUMMARY

Example embodiments provide a cell string included in a memory cell array of a nonvolatile memory device capable of reducing the number of manufacturing processes and improving the cell density.

Example embodiments provide a method of erasing a cell string included in a memory cell array of a nonvolatile memory device capable of reducing the number of manufacturing processes and improving the cell density.

According to example embodiments, a cell string included in a memory cell array of a nonvolatile memory device includes a plurality of memory cells, a string select transistor and a ground select transistor. The plurality of memory cells are connected in series. The string select transistor is connected between a bitline and the plurality of memory cells, and has a structure substantially the same as a structure of each memory cell. The ground select transistor is connected between the plurality of memory cells and a common source line, and has a structure substantially the same as the structure of each memory cell.

In some embodiments, the plurality of memory cells, the string select transistor, and the ground select transistor may be formed as floating gate memory cells. Each of the plurality of memory cells, the string select transistor, and the ground select transistor may include a source and a drain formed in a semiconductor substrate, a tunnel dielectric layer formed on the semiconductor substrate, a floating gate formed on the tunnel dielectric layer, a blocking dielectric layer formed on the floating gate, and a control gate formed on the blocking dielectric layer.

In other embodiments, the plurality of memory cells, the string select transistor, and the ground select transistor may be formed as charge trapping memory cells. Each of the plurality of memory cells, the string select transistor, and the ground select transistor may include a source and a drain formed in a semiconductor substrate, a tunnel dielectric layer formed on the semiconductor substrate, a charge trapping layer formed on the tunnel dielectric layer, a blocking dielectric layer formed on the charge trapping layer, and a control gate formed on the blocking dielectric layer.

The string select transistor and the ground select transistor may be erased when the plurality of memory cells are erased.

The string select transistor and the ground select transistor may be programmed after the plurality of memory cells are erased.

In some embodiments, the string select transistor and the ground select transistor may be programmed by hot carrier injection.

In other embodiments, the string select transistor and the ground select transistor may be programmed by Fowler-Nordheim tunneling.

The cell string may further include a first dummy memory cell connected between the string select transistor and the plurality of memory cells, and a second dummy memory cell connected between the plurality of memory cells and the ground select transistor.

According to example embodiments, a cell string included in a memory cell array of a nonvolatile memory device includes a plurality of memory cells, a plurality of string select transistors and a plurality of ground select transistors. The plurality of memory cells are connected in series. The plurality of string select transistors are connected in series between a bitline and the plurality of memory cells. Each string select transistor has a structure substantially the same as a structure of each memory cell. The plurality of ground select transistors are connected in series between the plurality of memory cells and a common source line. Each ground select transistor has a structure substantially the same as the structure of each memory cell.

The plurality of string select transistors may be connected to a single string select line.

The plurality of ground select transistors may be connected to a single ground select line.

In a method of erasing a cell string included in a memory cell array of a nonvolatile memory device according to example embodiments, a string select transistor, a plurality of memory cells and a ground select transistor that are connected in series are erased. The string select transistor and the ground select transistor are programmed.

To program the string select transistor and the ground select transistor, the string select transistor may be programmed, and the ground select transistor may be programmed after the string select transistor is programmed.

To program the string select transistor, a first pass voltage may be applied to the plurality of memory cells and the ground select transistor, a ground voltage may be applied to a common source line connected to the ground select transistor, a drain program voltage may be applied to a bitline connected to the string select transistor, and an incremental step pulse program voltage may be applied to the string select transistor. It may be verified whether the string select transistor is programmed, and the ground voltage may be applied to the bitline if the string select transistor is programmed.

To program the ground select transistor after the string select transistor is programmed, a first pass voltage may be applied to the plurality of memory cells, a second pass voltage having a voltage level higher than a voltage level of the first pass voltage may be applied to the string select transistor, a ground voltage may be applied to a common source line connected to the ground select transistor, a drain program voltage may be applied to a bitline connected to the string select transistor, and an incremental step pulse program voltage may be to the ground select transistor.

To program the string select transistor, a pass voltage may be applied to the plurality of memory cells and the ground select transistor, a ground voltage may be applied to a common source line connected to the ground select transistor and to a bitline connected to the string select transistor, and a program voltage may be applied to the string select transistor.

To program the string select transistor and the ground select transistor comprises, the ground select transistor may be programmed, and the string select transistor may be programmed after the ground select transistor is programmed.

### BRIEF DESCRIPTION OF THE DRAWINGS

FIG. 1 is a cross-sectional view of a cell string according to example embodiments.

FIG. 2 is a cross-sectional view of a floating gate memory cell as an example of each of a string select transistor, memory cells, and a ground select transistor included in a cell string of FIG. 1.

FIG. 3 is a cross-sectional view of a charge trapping memory cell as an example of each of a string select transistor, memory cells, and a ground select transistor included in a cell string of FIG. 1.

FIG. 4 is a circuit diagram illustrating a memory cell array including a cell string of FIG. 1.

FIG. 5 is a flow chart illustrating a method of erasing a cell string included in a memory cell array of FIG. 4 according to example embodiments.

FIG. 6 is a flow chart illustrating a method of programming string select transistors included in a memory cell array of FIG. 4 according to example embodiments.

FIG. 7A is a diagram illustrating voltages applied to a cell string of FIG. 1 including a string select transistor that is to be programmed while the method of FIG. 6 is performed.

FIG. 7B is a diagram illustrating voltages applied to a cell string of FIG. 1 including a string select transistor that is previously programmed while the method of FIG. 6 is performed.

FIG. 8 is a flow chart illustrating a method of programming ground select transistors included in a memory cell array of FIG. 4 according to example embodiments.

FIG. 9A is a diagram illustrating voltages applied to a cell string of FIG. 1 including a ground select transistor that is to be programmed while the method of FIG. 8 is performed.

FIG. 9B is a diagram illustrating voltages applied to a cell string of FIG. 1 including a ground select transistor that is previously programmed while the method of FIG. 8 is performed.

FIG. 10 is a flow chart illustrating a method of programming string select transistors and ground select transistors included in a memory cell array of FIG. 4 according to other example embodiments.

FIG. 11A is a diagram illustrating voltages applied to a cell string of FIG. 1 while a string select transistor is programmed by the method of FIG. 10.

FIG. 11B is a diagram illustrating voltages applied to a cell string of FIG. 1 while a ground select transistor is programmed by the method of FIG. 10.

FIG. 12 is a cross-sectional view of a cell string according to other example embodiments.

FIG. 13 is a circuit diagram illustrating a memory cell array including a cell string of FIG. 12.

FIG. 14 is a cross-sectional view of a cell string according to still other example embodiments.

FIG. 15 is a circuit diagram illustrating a memory cell array including a cell string of FIG. 14.

FIG. 16 is a block diagram illustrating a nonvolatile memory device according to example embodiments.

FIG. 17 is a block diagram illustrating a nonvolatile memory system according to example embodiments.

FIG. 18 is a block diagram illustrating a computing system according to example embodiments.

### DETAILED DESCRIPTION OF THE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

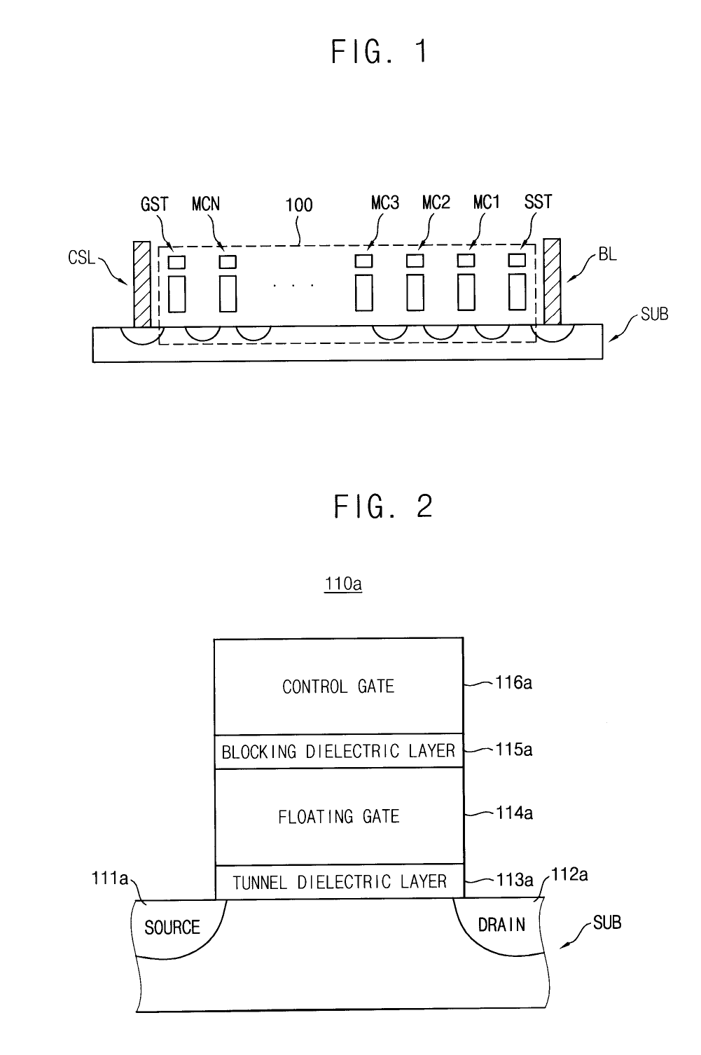

FIG. 1 is a cross-sectional view of a cell string according to example embodiments.

Referring to FIG. 1, a cell string 100 includes a plurality of memory cells MC1, MC2, MC3 and MCN, a string select transistor SST and a ground select transistor GST.

The plurality of memory cells MC1, MC2, MC3 and MCN may store data, and may maintain the stored data even if power is not supplied. The plurality of memory cells MC1, MC2, MC3 and MCN are connected in series to each other. The plurality of memory cells MC1, MC2, MC3 and MCN may be connected in series such that each memory cell shares a source/drain formed in a semiconductor substrate SUB with an adjacent memory cell. In some embodiments, each memory cell MC1, MC2, MC3 and MCN may have a structure of a floating gate memory cell where a floating gate is formed between the semiconductor substrate SUB and a control gate. In other embodiments, each memory cell MC1, MC2, MC3 and MCN may have a structure of a charge trapping memory cell where a charge trapping layer is formed between the semiconductor substrate SUB and the control gate instead of the floating gate.

The string select transistor SST is connected between a bitline BL and the plurality of memory cells MC1, MC2, MC3 and MCN. The string select transistor SST may control an electrical connection between the bitline BL and the plurality of memory cells MC1, MC2, MC3 and MCN in response to a voltage of a string select line. The string select transistor SST has a structure substantially the same as that of each memory cell MC1, MC2, MC3 and MCN. For example, the string select transistor SST may have the structure of the floating gate memory cell when each memory cell MC1, MC2, MC3 and MCN has the structure of the floating gate memory cell, or may have the structure of the charge trapping memory cell when each memory cell MC1, MC2, MC3 and MCN has structure of the charge trapping memory cell.

The ground select transistor GST is connected between the plurality of memory cells MC1, MC2, MC3 and MCN and a common source line CSL. The ground select transistor GST may control an electrical connection between the plurality of memory cells MC1, MC2, MC3 and MCN and the common source line CSL in response to a voltage of a ground select line. The ground select transistor GST has a structure substantially the same as that of each memory cell MC1, MC2, MC3 and MCN. For example, the ground select transistor GST may have the structure of the floating gate memory cell when each memory cell MC1, MC2, MC3 and MCN has the structure of the floating gate memory cell, or may have the structure of the charge trapping memory cell when each memory cell MC1, MC2, MC3 and MCN has structure of the charge trapping memory cell.

Since the string select transistor SST and the ground select transistor GST have the structures substantially the same as that of each memory cell MC1, MC2, MC3 and MCN, the string select transistor SST and the ground select transistor GST may be formed by processes that are used to form the plurality of memory cells MC1, MC2, MC3 and MCN. Further, a butting process for forming a contact is not required, and the string select transistor SST and the ground select transistor GST need not have a large size for the butting process. Accordingly, the cell string 100 according to some example embodiments may reduce the number of manufacturing processes, and may improve the cell density.

FIG. 2 is a cross-sectional view of a floating gate memory cell as an example of each of a string select transistor, memory cells, and a ground select transistor included in a cell string of FIG. 1.

Referring to FIG. 2, a floating gate memory cell 110a includes a source 111a, a drain 112a, a tunnel dielectric layer 113a, a floating gate 114a, a blocking dielectric layer 115a and a control gate 116a. Each of a string select transistor SST, memory cells MC1, MC2, MC3 and MCN and a ground select transistor GST illustrated in FIG. 1 may be formed as the floating gate memory cell 110a.

The source 111a and the drain 112a are formed in a semiconductor substrate SUB. For example, the source 111a and the drain 112a may be heavily doped with n-type impurities in a p-type semiconductor substrate SUB. Each of the source 111a and the drain 112a may be shared by adjacent floating gate memory cells.

The tunnel dielectric layer 113a is formed on the semiconductor substrate SUB. For example, the tunnel dielectric layer 113a may be formed of silicon dioxide, silicon oxynitride, or high-k dielectric having a high dielectric constant.

The floating gate 114a is formed on the tunnel dielectric layer 113a. The floating gate 114a may be charged by hot carrier injection or by Fowler-Nordheim tunneling during a program operation, and may be discharged by Fowler-Nordheim tunneling during an erase operation. For example, the floating gate 114a may be formed of a conductive material, such as polycrystalline silicon, polycrystalline silicon germanium, metal, metal oxide, metal nitride, metal silicide, etc.

The blocking dielectric layer 115a is formed on the floating gate 114a. The floating gate 114a may be electrically isolated from the control gate 116a by the blocking dielectric layer 115a. For example, the blocking dielectric layer 115a may be formed of at least one dielectric material, such as silicon dioxide, silicon nitride, silicon oxynitride, etc. In some embodiments, the blocking dielectric layer 115a may be formed as an oxide-nitride-oxide (ONO) layer where silicon dioxide, silicon nitride, and silicon dioxide are sequentially formed.

The control gate 116a is formed on the blocking dielectric layer 115a. The control gate 116a of a memory cell is connected to a wordline, the control gate 116a of a string select transistor is connected to a string select line, and the control gate 116a of a ground select transistor is connected to a ground select line. For example, the control gate 116a may be formed of a conductive material, such as polycrystalline silicon, polycrystalline silicon germanium, metal, metal oxide, metal nitride, metal silicide, etc.

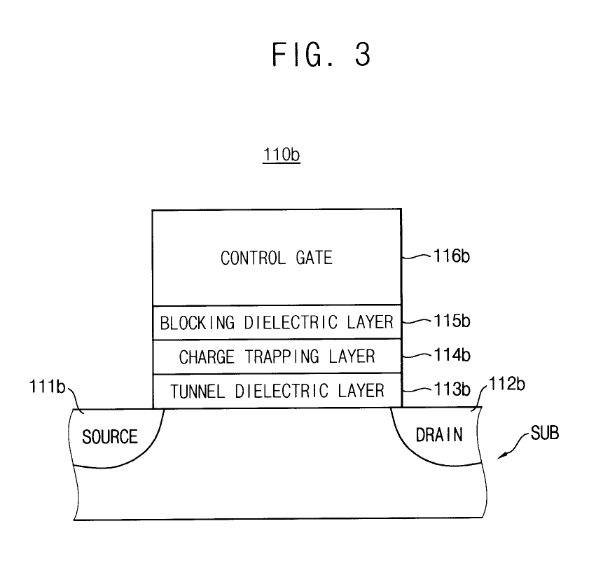

FIG. 3 is a cross-sectional view of a charge trapping memory cell as an example of each of a string select transistor, memory cells, and a ground select transistor included in a cell string of FIG. 1.

Referring to FIG. 3, a charge trapping memory cell 110b includes a source 111b, a drain 112b, a tunnel dielectric layer 113b, a charge trapping layer 114b, a blocking dielectric layer 115b and a control gate 116b. Each of a string select transistor SST, memory cells MC1, MC2, MC3 and MCN and a ground select transistor GST illustrated in FIG. 1 may be formed as the charge trapping memory cell 110b.

The charge trapping memory cell 110b includes stacked dielectric materials without a conductive floating gate 114a illustrated in FIG. 2 between a semiconductor substrate SUB and the control gate 116b. For example, the charge trapping memory cell 110b may have a silicon-oxide-nitride-oxide-silicon (SONOS) structure, in which the source 111b and the drain 112b is formed in a silicon semiconductor substrate SUB, the tunnel dielectric layer 113b of silicon dioxide is formed on the semiconductor substrate SUB, the charge trapping layer 114b of silicon nitride is formed on the tunnel dielectric layer 113b, the blocking dielectric layer 115b of silicon dioxide is formed on the charge trapping layer 114b, and the control gate 116b of polycrystalline silicon is formed on the blocking dielectric layer 115b. Since the charge trapping memory cell 110b has a structure similar to that of a conventional metal-oxide-semiconductor field effect transistor (MOSFET), the charge trapping memory cell 110b may be easily manufactured and may have a small size compared to a floating gate memory cell 110a of FIG. 2.

The tunnel dielectric layer 113b may be formed of a dielectric material, such as silicon dioxide. The tunnel dielectric layer 113b may be a single layer, or may be multiple layers having an ONO structure.

The charge trapping layer 114b is formed on the tunnel dielectric layer 113b. The charge trapping layer 114b may be formed of a dielectric material, such as silicon nitride, silicon oxynitride, silicon-rich nitride, silicon-rich oxide, etc.

The blocking dielectric layer 115b is formed on the charge trapping layer 114b. The blocking dielectric layer 115b may be formed of silicon dioxide, or a dielectric material having a dielectric constant higher than that of silicon dioxide. For example, the blocking dielectric layer 115b may be formed of aluminum oxide, hafnium oxide, titanium oxide, praseodymium oxide, zirconium oxide, lanthanum oxide, or a combination thereof.

The control gate 116b is formed on the blocking dielectric layer 115b. The control gate 116b may be formed of polycrystalline silicon, or metal having a work function higher than that of polycrystalline silicon. For example, the control gate 116b may be formed of platinum, aluminum, titanium, tantalum, tungsten, hafnium, niobium, molybdenum, iridium, cobalt, chromium, palladium, or compound thereof.

In other embodiments, the charge trapping memory cell 110b may includes nanoscale quantum dots instead of the charge trapping layer 114b. For example, the nanodot may be formed of silicon, germanium, silicon germanium, metal, metal oxide, metal nitride, or a combination thereof. In still other embodiments, the charge trapping memory cell 110b may have a structure of a fin-type flash memory cell or a structure of a stacked flash memory cell.

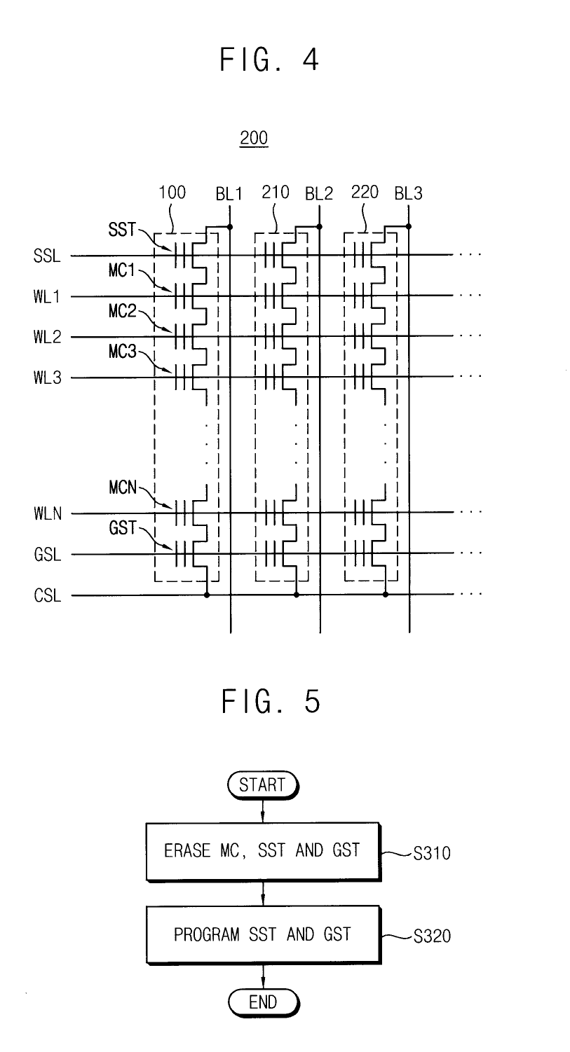

FIG. 4 is a circuit diagram illustrating a memory cell array including a cell string of FIG. 1.

Referring to FIG. 4, a memory cell array 200 includes a plurality of bitlines BL1, BL2 and BL3, a string select line SSL, a plurality of wordlines WL1, WL2, WL3 and WLN, a ground select line GSL, a common source line CSL and a plurality of cell strings 100, 210 and 220.

The plurality of cell strings 100, 210 and 220 are connected to the plurality of bitlines BL1, BL2 and BL3, respectively. Each cell string 100, 210 and 220 includes a string select transistor SST, a plurality of memory cells MC1, MC2, MC3 and MCN, and a ground select transistor GST that are connected in series.

A control gate of the string select transistor SST is connected to the string select line SSL, and the string select transistor SST may control an electrical connection between the plurality of memory cells MC1, MC2, MC3 and MCN and a corresponding bitline BL1 in response to a voltage of the string select line SSL. Control gates of the plurality of memory cells MC1, MC2, MC3 and MCN are connected to the plurality of wordlines WL1, WL2, WL3 and WLN, respectively. A control gate of the ground select transistor GST is connected to the ground select line GSL, and the ground select transistor GST may control an electrical connection between the plurality of memory cells MC1, MC2, MC3 and MCN and the common source line CSL in response to a voltage of the ground select line GSL.

FIG. 5 is a flow chart illustrating a method of erasing a cell string included in a memory cell array of FIG. 4 according to example embodiments.

Referring to FIGS. 4 and 5, a plurality of memory cells MC1, MC2, MC3 and MCN, a string select transistor SST and a ground select transistor GST are erased (step S310). Since each of the string select transistor SST and the ground select transistor GST has a structure substantially the same as that of each memory cell MC1, MC2, MC3 and MCN, the string select transistor SST and the ground select transistor GST, as well as the plurality of memory cells MC1, MC2, MC3 and MCN, are erased while an erase operation for a memory cell array 200 is performed. The erase operation may be performed in units of a block.

The erased string select transistor SST and the erased ground select transistor GST are programmed (step S320). Once the string select transistor SST and the ground select transistor GST are programmed, a program operation and a read operation for the memory cell array 200 may be performed using typical bias voltages by a conventional manner.

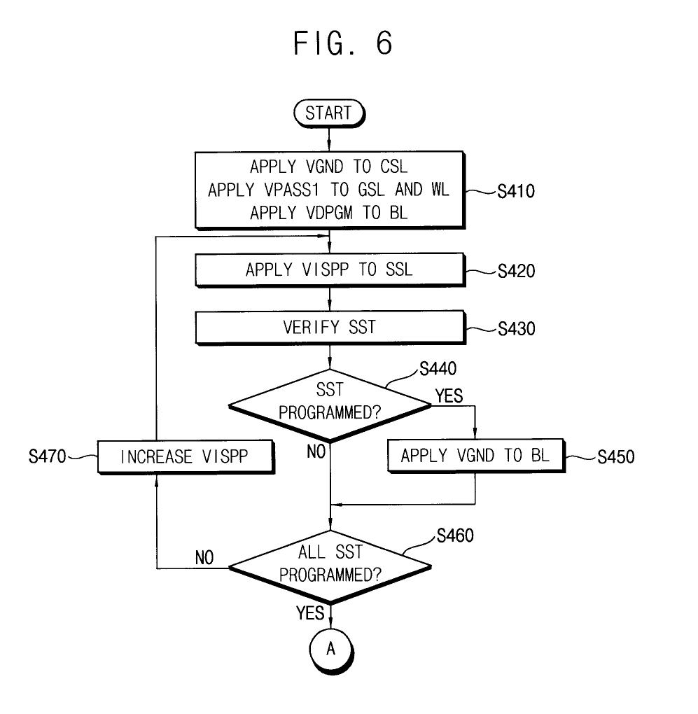

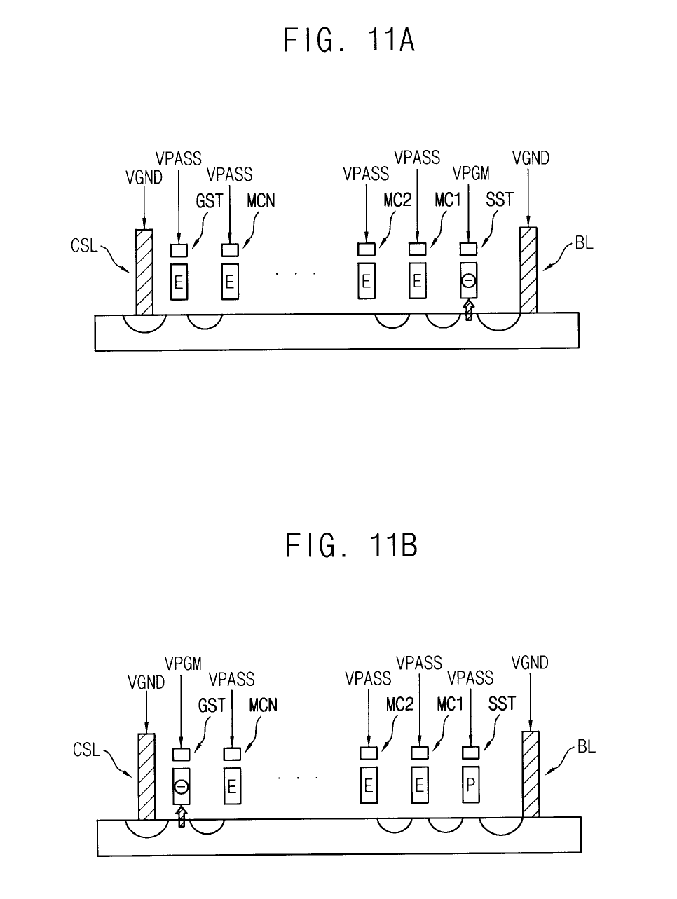

In some embodiments, as illustrated in FIGS. 6 through 9, the string select transistor SST and the ground select transistor GST may be programmed by hot carrier injection. In other embodiments, as illustrated in FIGS. 10 through 11B, the string select transistor SST and the ground select transistor GST may be programmed by Fowler-Nordheim tunneling.

Hereinafter, a method of programming the string select transistor SST and the ground select transistor GST using hot carrier injection according to some example embodiments will be described with reference to FIGS. 6 through 9B.

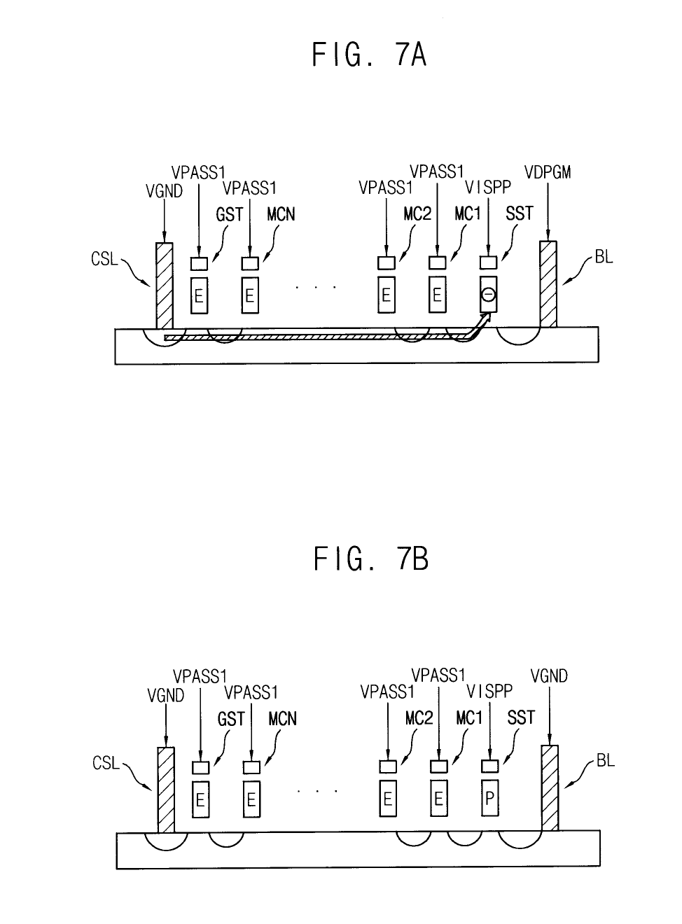

FIG. 6 is a flow chart illustrating a method of programming string select transistors included in a memory cell array of FIG. 4 according to example embodiments, FIG. 7A is a diagram illustrating voltages applied to a cell string of FIG. 1 including a string select transistor that is to be programmed while the method of FIG. 6 is performed, and FIG. 7B is a diagram illustrating voltages applied to a cell string of FIG. 1 including a string select transistor that is previously programmed while the method of FIG. 6 is performed.

Referring to FIGS. 4, 6, 7A and 7B, a ground voltage VGND is applied to a common source line CSL, a first pass voltage VPASS1 is applied to a ground select line GSL and wordlines WL1, WL2, WL3 and WLN, and a drain program voltage VDPGM is applied to bitlines BL1, BL2 and BL3 (step S410). The first pass voltage VPASS1 is applied to ground select transistors GST of cell strings 100, 210 and 220 through the ground select line GSL, and the ground select transistors GST are turned on in response to the first pass voltage VPASS1. The first pass voltage VPASS1 is also applied to memory cells MC1, MC2, MC3 and MCN through the wordlines WL1, WL2, WL3 and WLN, and the memory cells MC1, MC2, MC3 and MCN are turned on in response to the first pass voltage VPASS1. Accordingly, the ground voltage VGND may be applied to sources of string select transistors SST of the cell strings 100, 210 and 220 through the common source line CSL, the turned-on ground select transistors GST, and the turned-on memory cells MC1, MC2, MC3 and MCN. The drain program voltage VDPGM may be applied to drains of the string select transistors SST through the bitlines BL1, BL2 and BL3. For example, the first pass voltage VPASS1 may have a voltage level ranging from about 0 V to about 2 V, and the drain program voltage VDPGM may have a voltage level ranging from about 4 V to about 5 V.

An incremental step pulse program voltage VISPP is applied to a string select line SSL (step S420). The incremental step pulse program voltage VISPP is applied to control gates of the string select transistors SST of the cell strings 100, 210 and 220 through the string select line SSL. Since the ground voltage VGND is applied to the sources of string select transistors SST, the drain program voltage VDPGM is applied to the drains of the string select transistors SST, and the incremental step pulse program voltage VISPP is applied to the control gates of the string select transistors SST, the string select transistors SST may be programmed by hot carrier injection. For example, as illustrated in FIG. 7A, electrons of high energy may be injected into the string select transistor SST of each cell string 100, 210 and 220 based on a voltage difference between the source and the drain and the incremental step pulse program voltage VISPP.

It is verified whether the string select transistors SST of the cell strings 100, 210 and 220 are programmed (step S430). For example, the string select transistors SST are verified by applying a verify voltage to the control gates of the string select transistors SST through the string select line SSL.

If a string select transistor SST is programmed (step S440: YES), the ground voltage VGND is applied to a bitline BL corresponding to the programmed string select transistor SST (step S450). Even if the incremental step pulse program voltage VISPP is applied to the string select transistor SST, as illustrated in FIG. 7B, a threshold voltage level of the string select transistor SST may not be changed while the ground voltage VGND is applied to the common source line CSL and the bitline BL. If a string select transistor SST is still not programmed (step S440: NO), the drain program voltage VDPGM is again applied to a bitline BL corresponding to the string select transistor SST that is not programmed as illustrated in FIG. 7A.

If any one of the string select transistors SST of the cell strings 100, 210 and 220 is still not programmed (step S460: NO), a voltage level of the incremental step pulse program voltage VISPP is increased (step S470). For example, the incremental step pulse program voltage VISPP may gradually increase from about 0 V to about 8 V. A program operation and a verify operation for the string select transistors SST may be repeatedly performed while the incremental step pulse program voltage VISPP gradually increases.

If all of the string select transistors SST of the cell strings 100, 210 and 220 are programmed (step S460: YES), the method of programming the string select transistors SST is finished. After all of the string select transistors SST in a selected memory block are programmed, a program operation for the ground select transistors GST in the memory block may be performed.

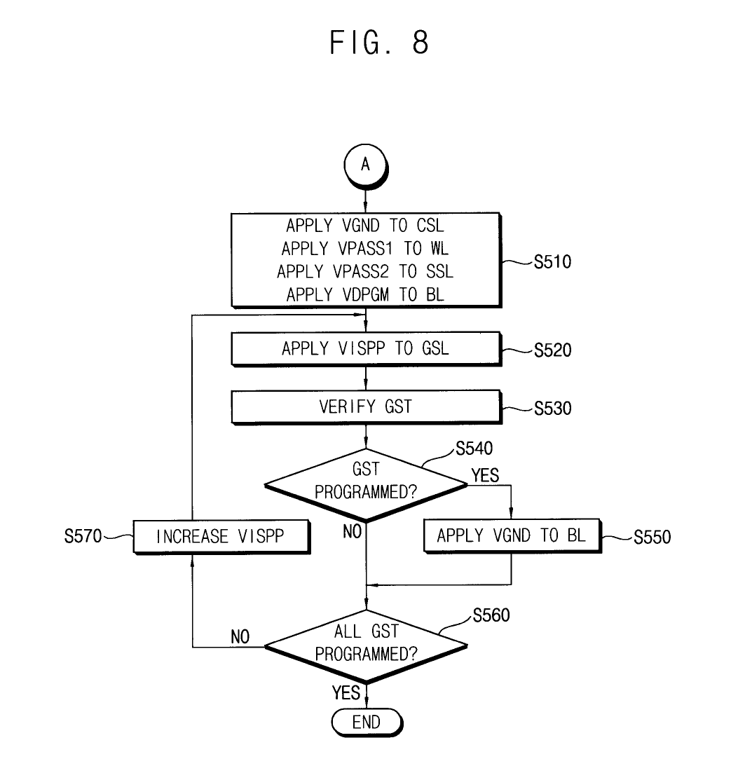

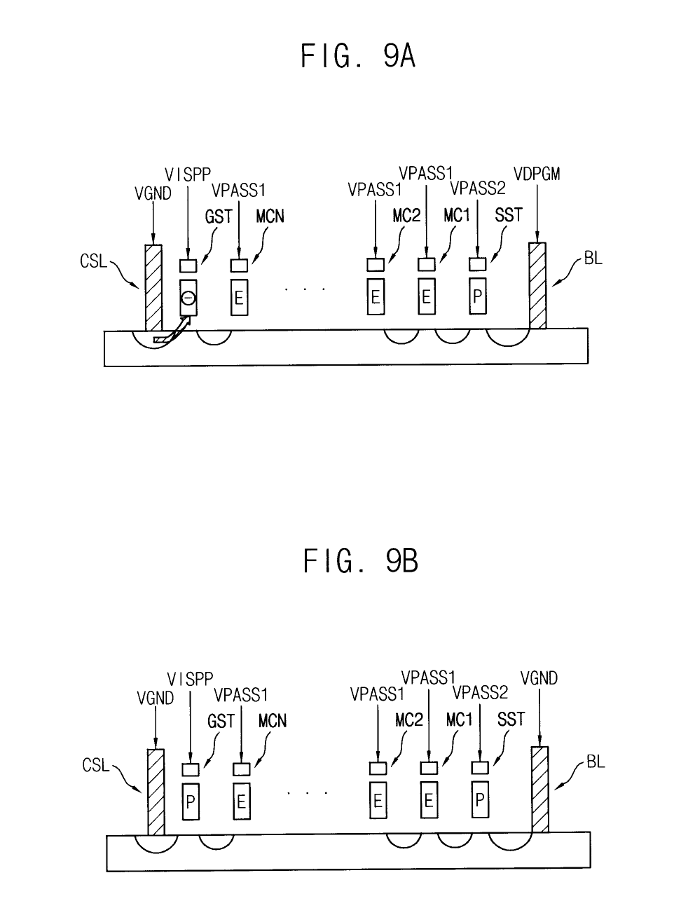

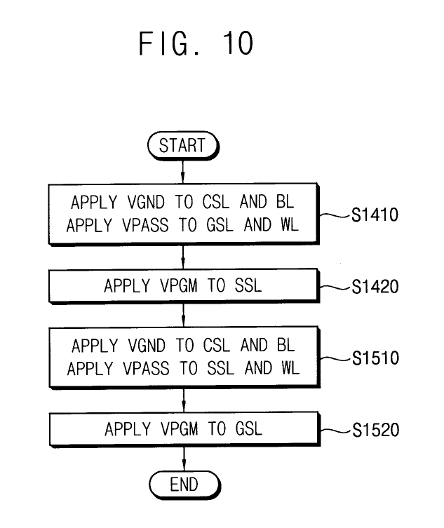

FIG. 8 is a flow chart illustrating a method of programming ground select transistors included in a memory cell array of FIG. 4 according to example embodiments, FIG. 9A is a diagram illustrating voltages applied to a cell string of FIG. 1 including a ground select transistor that is to be programmed while the method of FIG. 8 is performed, and FIG. 9B is a diagram illustrating voltages applied to a cell string of FIG. 1 including a ground select transistor that is previously programmed while the method of FIG. 8 is performed.

Referring to FIGS. 4, 8, 9A and 9B, a ground voltage VGND is applied to a common source line CSL, a first pass voltage VPASS1 is applied to wordlines WL1, WL2, WL3 and WLN, a second pass voltage VPASS2 is applied to a string select line SSL, and a drain program voltage VDPGM is applied to bitlines BL1, BL2 and BL3 (step S510). Memory cells MC1, MC2, MC3 and MCN are turned on in response to the first pass voltage VPASS1 applied through the wordlines WL1, WL2, WL3 and WLN. The second pass voltage VPASS2 is applied to string select transistors SST of cell strings 100, 210 and 220 through the string select line SSL, and the string select transistors SST are turned on in response to the second pass voltage VPASS2. Accordingly, the drain program voltage VDPGM may be applied to drains of ground select transistors GST of the cell strings 100, 210 and 220 through the bitlines BL1, BL2 and BL3, the turned-on string select transistors SST, and the turned-on memory cells MC1, MC2, MC3 and MCN. The ground voltage VGND may be applied to sources of the ground select transistors GST through the common source line CSL. The second pass voltage VPASS2 for turning on the string select transistors SST that are programmed may have a voltage level higher than that of the first pass voltage VPASS1 for turning on the memory cells MC1, MC2, MC3 and MCN that are erased. For example, the first pass voltage VPASS1 may have a voltage level ranging from about 0 V to about 2 V, and the second pass voltage VPASS2 may have a voltage level ranging from about 4 V to about 5 V.

An incremental step pulse program voltage VISPP is applied to a ground select line GSL (step S520). The incremental step pulse program voltage VISPP is applied to control gates of the ground select transistors GST of the cell strings 100, 210 and 220 through the ground select line GSL. Since the ground voltage VGND is applied to the sources of ground select transistors GST, the drain program voltage VDPGM is applied to the drains of the ground select transistors GST, and the incremental step pulse program voltage VISPP is applied to the control gates of the ground select transistors GST, the ground select transistors GST may be programmed by hot carrier injection. For example, as illustrated in FIG. 9A, electrons of high energy may be injected into the ground select transistor GST of each cell string 100, 210 and 220 based on a voltage difference between the source and the drain and the incremental step pulse program voltage VISPP.

It is verified whether the ground select transistors GST of the cell strings 100, 210 and 220 are programmed (step S530). For example, the ground select transistors GST are verified by applying a verify voltage to the control gates of the ground select transistors GST through the ground select line GSL.

If a ground select transistor GST is programmed (step S540: YES), the ground voltage VGND is applied to a bitline BL corresponding to the programmed ground select transistor GST (step S550). Even if the incremental step pulse program voltage VISPP is applied to the ground select transistor GST, as illustrated in FIG. 9B, a threshold voltage level of the ground select transistor GST may not be changed while the ground voltage VGND is applied to the common source line CSL and the bitline BL. If a ground select transistor GST is still not programmed (step S540: NO), the drain program voltage VDPGM is again applied to a bitline BL corresponding to the ground select transistor GST that is not programmed as illustrated in FIG. 9A.

If any one of the ground select transistors GST of the cell strings 100, 210 and 220 is still not programmed (step S560: NO), a voltage level of the incremental step pulse program voltage VISPP is increased (step S570). For example, the incremental step pulse program voltage VISPP may gradually increase from about 0 V to about 8 V. A program operation and a verify operation for the ground select transistors GST may be repeatedly performed while the incremental step pulse program voltage VISPP gradually increases.

If all of the ground select transistors GST of the cell strings 100, 210 and 220 are programmed (step S560: YES), the method of programming the ground select transistors GST is finished. As described above, when an erase operation for a memory cell array 200 is performed, the string select transistors SST and the ground select transistors GST may be programmed by hot carrier injection.

Although an example, in which the ground select transistors GST are programmed after the string select transistors SST are programmed, is illustrated in FIGS. 6 through 9, in some embodiments, the string select transistors SST may be programmed after the ground select transistors GST are programmed.

In case where the string select transistors SST are programmed after the ground select transistors GST are programmed, the ground voltage VGND may be applied to the common source line CSL, and the first pass voltage VPASS1 may be applied to the string select line SSL and the wordlines WL1, WL2, WL3 and WLN to program the ground select transistors GST. The drain program voltage VDPGM may be applied to a bitline BL corresponding to a ground select transistor GST that is to be programmed, and the ground voltage VGND may be applied to a bitline BL corresponding to a ground select transistor GST that is previously programmed.

When the string select transistors SST are programmed after the ground select transistors GST are programmed, the ground voltage VGND may be applied to the common source line CSL, the first pass voltage VPASS1 may be applied to the wordlines WL1, WL2, WL3 and WLN, and the second pass voltage VPASS2 may be applied to the ground select line GSL. The drain program voltage VDPGM may be applied to a bitline BL corresponding to a string select transistor SST that is to be programmed, and the ground voltage VGND may be applied to a bitline BL corresponding to a string select transistor SST that is previously programmed. Accordingly, the string select transistors SST are programmed after the ground select transistors GST are programmed.

Hereinafter, a method of programming the string select transistor SST and the ground select transistor GST using Fowler-Nordheim tunneling according to other example embodiments will be described with reference to FIGS. 10 through 11B.

FIG. 10 is a flow chart illustrating a method of programming string select transistors and ground select transistors included in a memory cell array of FIG. 4 according to other example embodiments, FIG. 11A is a diagram illustrating voltages applied to a cell string of FIG. 1 while a string select transistor is programmed by the method of FIG. 10, and FIG. 11B is a diagram illustrating voltages applied to a cell string of FIG. 1 while a ground select transistor is programmed by the method of FIG. 10.

Referring to FIGS. 4, 10, 11A and 11B, a ground voltage VGND is applied to a common source line CSL and bitlines BL1, BL2 and BL3, and a pass voltage VPASS is applied to a ground select line GSL and wordlines WL1, WL2, WL3 and WLN (step S1410). The pass voltage VPASS is applied to ground select transistors GST of cell strings 100, 210 and 220 through the ground select line GSL, and the ground select transistors GST are turned on in response to the pass voltage VPASS. The pass voltage VPASS is also applied to memory cells MC1, MC2, MC3 and MCN through the wordlines WL1, WL2, WL3 and WLN, and the memory cells MC1, MC2, MC3 and MCN are turned on in response to the pass voltage VPASS. The ground voltage VGND may be applied to sources of string select transistors SST of the cell strings 100, 210 and 220 through the common source line CSL, the turned-on ground select transistors GST, and the turned-on memory cells MC1, MC2, MC3 and MCN. The ground voltage VGND may be applied to drains of the string select transistors SST through the bitlines BL1, BL2 and BL3. Accordingly, channels of the string select transistors SST may be grounded. The pass voltage VPASS may have a voltage level for turning on the ground select transistors GST and the memory cells MC1, MC2, MC3 and MCN regardless of whether the ground select transistors GST and the memory cells MC1, MC2, MC3 and MCN are programmed or erased. For example, the pass voltage VPASS may have a voltage level ranging from about 8 V to about 9 V.

A program voltage VPGM is applied to a string select line SSL (step S1420). The program voltage VPGM is applied to control gates of the string select transistors SST of the cell strings 100, 210 and 220 through the string select line SSL. As illustrated in FIG. 11A, the string select transistor SST may be programmed by Fowler-Nordheim tunneling based on a voltage difference between a voltage of the grounded channel of the string select transistor SST and the program voltage VPGM.

In some embodiments, the program voltage VPGM may be an incremental step pulse program voltage VISPP that gradually increases. For example, the program voltage VPGM may be applied to the string select line SSL about ten times while gradually increasing by about 0.1 V from about 15 V to about 16 V. Since a read operation for the string select transistors SST is not performed, a threshold voltage distribution of the string select transistors SST need not be as narrow as that of the memory cells MC1, MC2, MC3 and MCN. Accordingly, when an incremental step pulse program operation for the string select transistors SST is performed, a verify operation for the string select transistors SST may not be performed in some embodiments.

After the string select transistors SST are programmed, the ground voltage VGND is applied to the common source line CSL and the bitlines BL1, BL2 and BL3, and the pass voltage VPASS is applied to the string select line SSL and the wordlines WL1, WL2, WL3 and WLN (step S1510). The pass voltage VPASS is applied to the string select transistors SST of the cell strings 100, 210 and 220 through the string select line SSL, and the string select transistors SST are turned on in response to the pass voltage VPASS. The pass voltage VPASS is also applied to the memory cells MC1, MC2, MC3 and MCN through the wordlines WL1, WL2, WL3 and WLN, and the memory cells MC1, MC2, MC3 and MCN are turned on in response to the pass voltage VPASS. The ground voltage VGND may be applied to drains of the ground select transistors GST of the cell strings 100, 210 and 220 through the bitlines BL1, BL2 and BL3, the turned-on string select transistors SST, and the turned-on memory cells MC1, MC2, MC3 and MCN. The ground voltage VGND may also be applied to sources of the ground select transistors GST through the ground select line GSL. Accordingly, channels of the ground select transistors GST may be grounded. The pass voltage VPASS may have a voltage level for turning on the string select transistors SST and the memory cells MC1, MC2, MC3 and MCN regardless of whether the string select transistors SST and the memory cells MC1, MC2, MC3 and MCN are programmed or erased. For example, the pass voltage VPASS may have a voltage level ranging from about 8 V to about 9 V.

The program voltage VPGM is applied to the ground select line GSL (step S1520). The program voltage VPGM is applied to control gates of the ground select transistors GST of the cell strings 100, 210 and 220 through the ground select line GSL. As illustrated in FIG. 11B, the ground select transistor GST may be programmed by Fowler-Nordheim tunneling based on a voltage difference between a voltage of the grounded channel of the ground select transistor GST and the program voltage VPGM. In some embodiments, the program voltage VPGM may be the incremental step pulse program voltage VISPP that gradually increases. When an incremental step pulse program operation for the ground select transistors GST is performed, a verify operation for the ground select transistors GST may not be performed in some embodiments.

As described above, when an erase operation for a memory cell array 200 is performed, the string select transistors SST and the ground select transistors GST of the cell strings 100, 210 and 220 are programmed by Fowler-Nordheim tunneling.

Although an example, in which the ground select transistors GST are programmed after the string select transistors SST are programmed, is illustrated in FIGS. 10 through 11B, in some embodiments, the string select transistors SST may be programmed after the ground select transistors GST are programmed.

In case where the string select transistors SST are programmed after the ground select transistors GST are programmed, the ground voltage VGND is applied to the common source line CSL and the bitline BL, the pass voltage VPASS is applied to the string select line SSL and the wordlines WL1, WL2, WL3 and WLN, and the program voltage VPGM is applied to the ground select line GSL to program the ground select transistors GST.

After the ground select transistors GST are programmed, the ground voltage VGND is applied to the common source line CSL and the bitline BL, the pass voltage VPASS is applied to the ground select line GSL and the wordlines WL1, WL2, WL3 and WLN, and the program voltage VPGM is applied to the string select line SSL. Accordingly, the string select transistors SST are programmed after the ground select transistors GST are programmed.

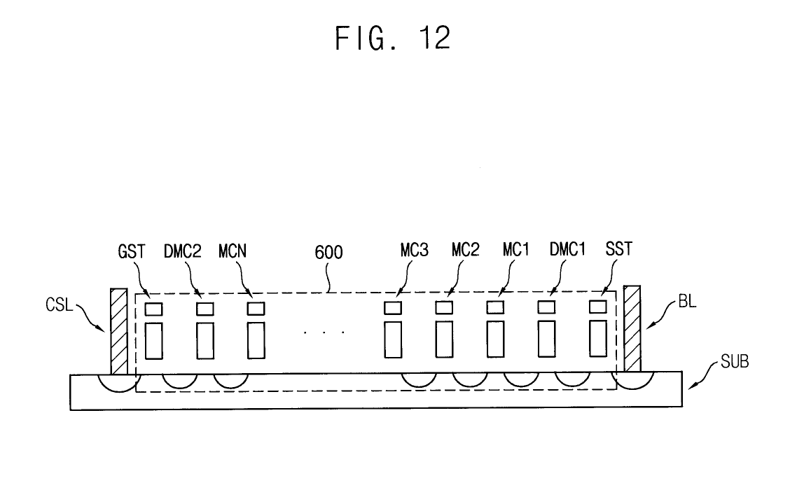

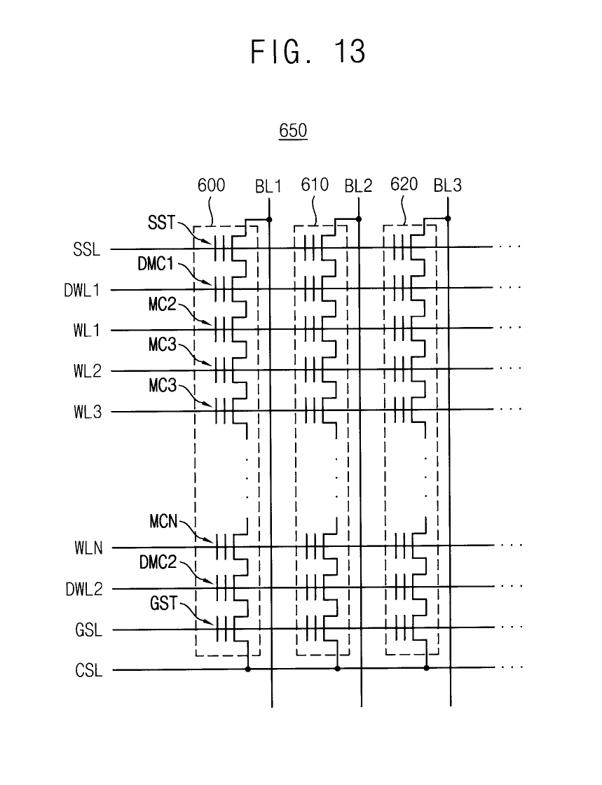

FIG. 12 is a cross-sectional view of a cell string according to other example embodiments.

Referring to FIG. 12, a cell string 600 includes a plurality of memory cells MC1, MC2, MC3 and MCN, a string select transistor SST, a ground select transistor GST, a first dummy memory cell DMC1 and a second dummy memory cell DMC2. Compared to a cell string of FIG. 1, the cell string 600 may further include the first dummy memory cell DMC1 and the second dummy memory cell DMC2.

The first dummy memory cell DMC1 is connected between a first memory cell MC1 and the string select transistor SST, and the second dummy memory cell DMC2 is connected between an n-th memory cell MCN and the ground select transistor GST. Each of the first dummy memory cell DMC1 and the second dummy memory cell DMC2 may have a structure substantially the same as that of each of the memory cells MC1, MC2, MC3 and MCN, the string select transistor SST, and the ground select transistor GST. The first dummy memory cell DMC1 may prevent a program disturb between the first memory cell MC1 and the string select transistor SST, and the second dummy memory cell DMC2 may prevent a program disturb between the n-th memory cell MCN and the ground select transistor GST.

FIG. 13 is a circuit diagram illustrating a memory cell array including a cell string of FIG. 12.

Referring to FIG. 13, a memory cell array 650 includes a plurality of bitlines BL1, BL2 and BL3, a string select line SSL, a plurality of wordlines WL1, WL2, WL3 and WLN, a ground select line GSL, a common source line CSL, a first dummy wordline DWL1, a second dummy wordline DWL2 and a plurality of cell strings 100, 210 and 220. Compared to a memory cell array of FIG. 4, the memory cell array 650 may further include a plurality of dummy memory cells DMC1 and DMC2, the first dummy wordline DWL1 and the second dummy wordline DWL2.

The first dummy wordline DWL1 is connected to control gates of first dummy memory cells DMC1 of the cell strings 100, 210 and 220, and the second dummy wordline DWL2 is connected to control gates of second dummy memory cells DMC2 of the cell strings 100, 210 and 220. The dummy memory cells DMC1 and DMC2 may not store data. When a program operation and a read operation for the memory cell array 650 are performed, a voltage applied to the first dummy wordline DWL1 and the second dummy wordline DWL2 may be substantially the same as a voltage applied to a non-selected wordline.

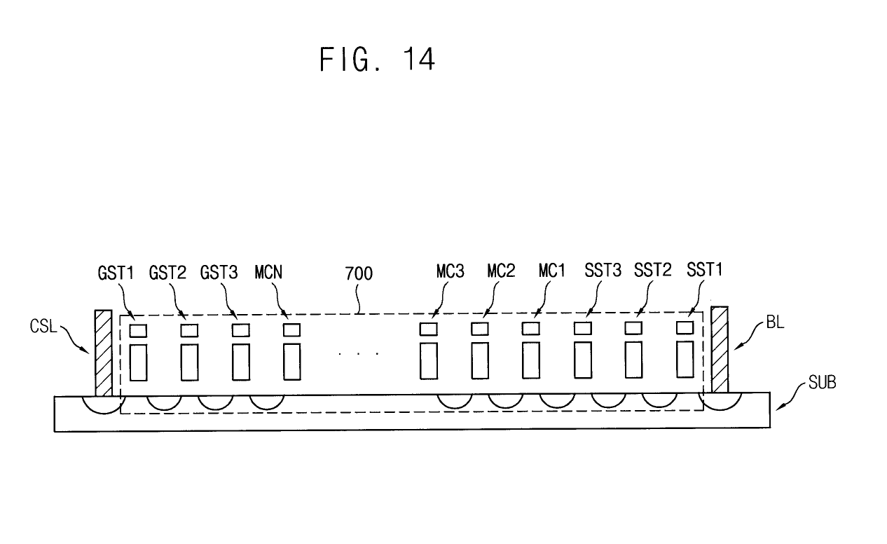

FIG. 14 is a cross-sectional view of a cell string according to still other example embodiments.

Referring to FIG. 14, a cell string 700 includes a plurality of memory cells MC1, MC2, MC3 and MCN, a plurality of string select transistors SST1, SST2 and SST3, a plurality of ground select transistors GST1, GST2 and GST3. Compared to a cell string of FIG. 1, the cell string 700 may further include at least one string select transistor SST2 and SST3 and at least one ground select transistor GST2 and GST3.

The plurality of string select transistors SST1, SST2 and SST3 may be connected in series such that each string select transistor shares a source/drain formed in a semiconductor substrate SUB with an adjacent string select transistor. Similarly, the plurality of ground select transistors GST1, GST2 and GST3 may be connected in series such that each ground select transistor shares a source/drain formed in the semiconductor substrate SUB with an adjacent ground select transistor. In the cell string 700, a sufficient channel length of a string select transistor is provided by the plurality of string select transistors SST1, SST2 and SST3 that are connected in series, and a sufficient channel length of a ground select transistor is provided by the plurality of ground select transistors GST1, GST2 and GST3 that are connected in series.

In some embodiments, the cell string 700 may further include a first dummy memory cell connected between a third string select transistor SST3 and a first memory cell MC1, and a second dummy memory cell connected between a third ground select transistor GST3 and an n-th memory cell MCN.

Although the cell string 700 is illustrated in FIG. 14 as including three string select transistors SST1, SST2 and SST3 and three ground select transistors GST1, GST2 and GST3, the cell string 700 may include two or more string select transistors and two or more ground select transistors.

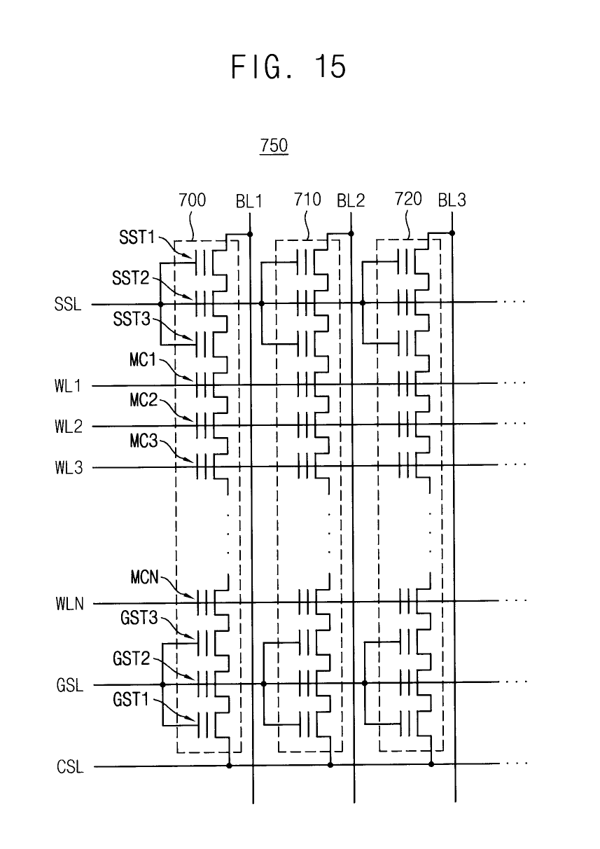

FIG. 15 is a circuit diagram illustrating a memory cell array including a cell string of FIG. 14.

Referring to FIG. 15, a memory cell array 750 includes a plurality of bitlines BL1, BL2 and BL3, a string select line SSL, a plurality of wordlines WL1, WL2, WL3 and WLN, a ground select line GSL, a common source line CSL and a plurality of cell strings 100, 210 and 220. Compared to a memory cell array of FIG. 4, the memory cell array 750 may further include at least one string select transistor SST2 and SST3 and at least one ground select transistor GST2 and GST3 per each cell string.

A plurality of string select transistors SST1, SST2 and SST3 of the cell strings 100, 210 and 220 may be connected to the same string select line SSL, and a plurality of ground select transistors GST1, GST2 and GST3 of the cell strings 100, 210 and 220 may be connected to the same ground select line GSL. Accordingly, an erase operation, a program operation and a read operation for the memory cell array 750 may be similar to those for a memory cell array 200 of FIG. 4.

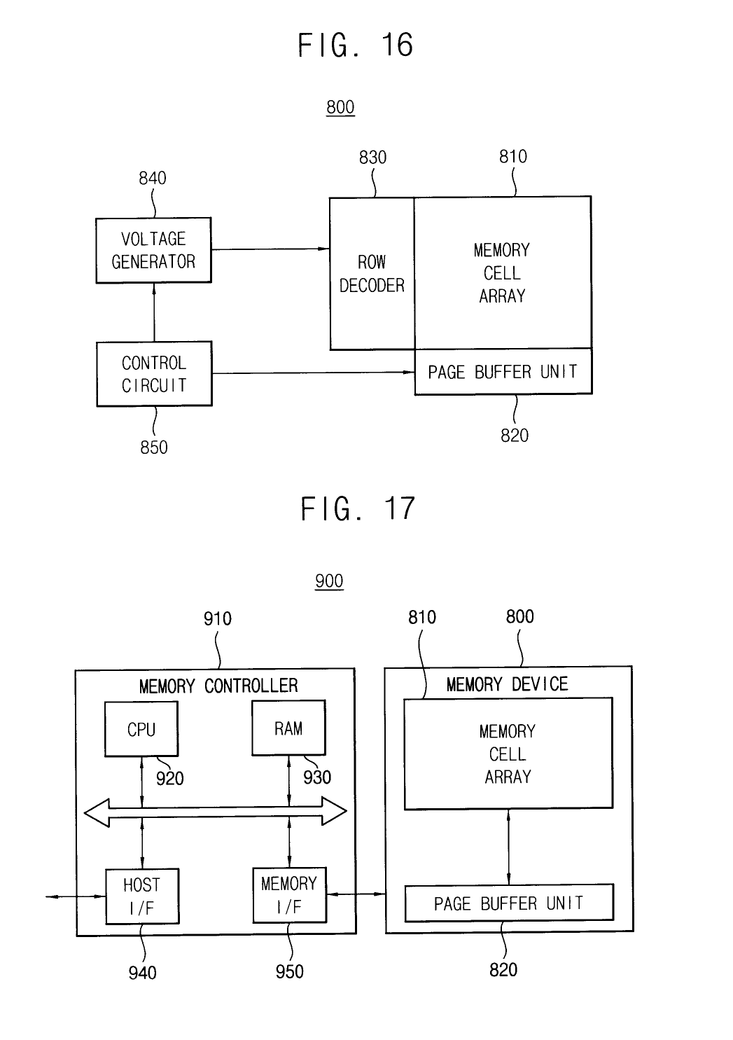

FIG. 16 is a block diagram illustrating a nonvolatile memory device according to example embodiments.

Referring to FIG. 16, a nonvolatile memory device 800 comprises a memory cell array 810, a page buffer unit 820, a row decoder 830, a voltage generator 840, and a control circuit 850. The memory cell array 810 may include a memory cell array 200 of FIG. 4, a memory cell array 650 of FIG. 13, or a memory cell array 750 of FIG. 15.

The memory cell array 810 includes a plurality of cell strings. Each cell string may include a string select transistor, a plurality of memory cells, and a ground select transistor that are connected in series. Each of the string select transistor and the ground select transistor may have a structure substantially the same as that of each memory cell. Accordingly, the memory cell array 810 may reduce the number of manufacturing processes, and may improve the cell density. Each memory cell may be a single level cell that stores one bit of data, or a multi-level cell that stores multiple bits of data.

The voltage generator 840 is controlled by the control circuit 850 and generates wordline voltages, such as a program voltage, a pass voltage, a verify voltage, a read voltage, and so on. The row decoder 830 selects a wordline in response to a row address, and transfers the wordline voltages from the voltage generator 840 to selected and non-selected wordlines. During a program operation, the row decoder 830 may apply the program voltage to the selected wordline, and may apply the pass voltage to the non-selected wordlines.

The page buffer unit 820 operates as a write driver or a sense amplifier for the memory cell array 810 based on an operating mode of the nonvolatile memory device 800. For example, the page buffer unit 820 may operate as the sense amplifier in a read mode, and may operate as the write driver in a program mode. The page buffer unit 820 may include a plurality of page buffers connected to a plurality of bitlines, respectively. Each page buffer may temporarily store data to be programmed in a memory cell.

The control circuit 850 may control the page buffer unit 820, the row decoder 830, and the voltage generator 840 to program data provided from an external controller in the memory cell array 810.

FIG. 17 is a block diagram illustrating a nonvolatile memory system according to example embodiments.

Referring to FIG. 17, a nonvolatile memory system 900 includes a nonvolatile memory device 800 and a memory controller 910.

The nonvolatile memory device 800 includes a memory cell array 810 and a page buffer unit 820. The memory cell array 810 may include a plurality of memory cells connected to a plurality of wordlines and a plurality of bitlines. The page buffer unit 820 may temporarily store data to be programmed in the plurality of memory cells.

The memory controller 910 may control data transfer between an external host and the nonvolatile memory device 800. The memory controller 910 may include a central processing unit (CPU) 920, a buffer memory 930, a host interface 940 and a memory interface 950. The CPU 920 may perform the data transfer. The buffer memory 930 may temporarily store data provided from the host or data read from the nonvolatile memory device 800. The memory controller 910 may load the data provided from the host to the page buffer unit 820 of the nonvolatile memory device 800. The host interface 940 is connected to the host, and the memory interface 950 is connected to the nonvolatile memory device 800. The CPU 920 may communicate with the host through the host interface 940, and may communicate with the nonvolatile memory device 800 through the memory interface 950.

In some embodiments, the buffer memory 930 may include a dynamic random access memory (DRAM), a static random access memory (SRAM), a phase random access memory (PRAM), a ferroelectric random access memory (FRAM), a resistive random access memory (RRAM), a magnetic random access memory (MRAM), or another form of volatile or nonvolatile memory. The buffer memory 930 may operate as a working memory of the CPU 920.

In some embodiments, the nonvolatile memory system 900 is incorporated into a memory card, a solid state drive (SSD), or other potentially standalone memory product. In various alternative embodiments, the memory controller 910 may communicate with the host through a universal serial bus (USB) interface, a multi media card (MMC) interface, a peripheral component interconnect express (PCI-E) interface, an advanced technology attachment (ATA) interface, a serial ATA interface, a parallel ATA interface, a small computer system interface (SCSI), an enhanced small device (ESD) interface, an integrated drive electronics (IDE) interface, or the like.

The nonvolatile memory device 800 and/or the memory controller 910 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

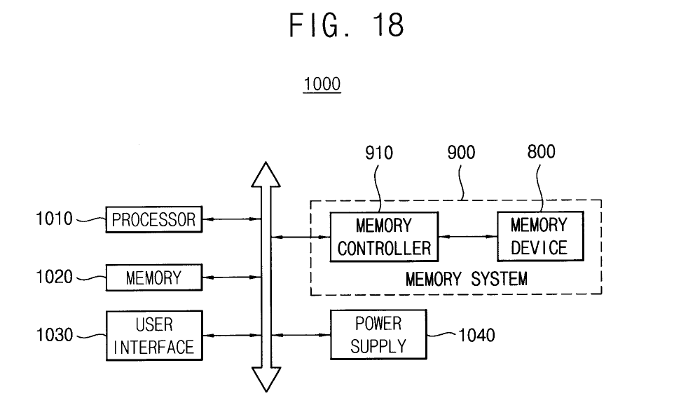

FIG. 18 is a block diagram illustrating a computing system according to example embodiments.

Referring to FIG. 18, a computing system 1000 includes a processor 1010, a memory device 1020, a user interface 1030, and a nonvolatile memory system 900.

The processor 1010 performs various computing functions, such as executing specific software for performing specific calculations or tasks. The processor 1010 may include a microprocessor or a CPU. The processor 1010 is typically connected to the memory device 1020 via an address bus, a control bus and/or a data bus. The memory device 1020 may include a volatile memory such as a DRAM or SRAM, or a non-volatile memory such as an erasable programmable read-only memory (EPROM) or an electrically erasable programmable read-only memory (EEPROM). The processor 1010 may be connected to an expansion bus, such as a peripheral-component-interconnect (PCI) bus. The processor 1010 controls the user interface 1030, which may include, for instance, an input device (e.g., a keyboard or a mouse), an output device (e.g., a printer or a display device) and a storage device (e.g., a hard disk drive or a compact disk read-only memory (CD-ROM)). The computing system 1000 further includes a power supply 1040 for supplying operational power. The computing system 1000 may further include an application chipset, a camera image processor (CIS), and a mobile DRAM.

The computing system 1000 can be used to implement any of several different electronic devices, such as a mobile phone, a personal digital assistant (PDA), a digital camera, a gaming machine, a portable multimedia player (PMP), a music player, a desktop computer, a notebook computer, a speaker, a video player, a television, a smart phone, a handheld computer, or a universal serial bus (USB) device, to name but a few.

As indicated by the above description, a cell string included in a memory cell array and a method of erasing a cell string included in a memory cell array according to example embodiments may reduce the number of manufacturing processes and may improve the cell density since a string select transistor and a ground select transistor may have structures substantially the same as those of memory cells.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A cell string included in a memory cell array of a nonvolatile memory device, the cell string comprising:
a plurality of memory cells connected in series;
a string select transistor connected between a bitline and the plurality of memory cells, the string select transistor having a structure substantially the same as a structure of each memory cell; and
a ground select transistor connected between the plurality of memory cells and a common source line, the ground select transistor having a structure substantially the same as the structure of each memory cell.

2. The cell string of claim 1, wherein the plurality of memory cells, the string select transistor, and the ground select transistor are formed as floating gate memory cells.

3. The cell string of claim 2, wherein each of the plurality of memory cells, the string select transistor, and the ground select transistor comprises:
a source and a drain formed in a semiconductor substrate;
a tunnel dielectric layer formed on the semiconductor substrate;
a floating gate formed on the tunnel dielectric layer;
a blocking dielectric layer formed on the floating gate; and
a control gate formed on the blocking dielectric layer.

4. The cell string of claim 1, wherein the plurality of memory cells, the string select transistor, and the ground select transistor are formed as charge trapping memory cells.

5. The cell string of claim 4, wherein each of the plurality of memory cells, the string select transistor, and the ground select transistor comprises:
a source and a drain formed in a semiconductor substrate;
a tunnel dielectric layer formed on the semiconductor substrate;
a charge trapping layer formed on the tunnel dielectric layer;
a blocking dielectric layer formed on the charge trapping layer; and
a control gate formed on the blocking dielectric layer.

6. The cell string of claim 1, wherein the string select transistor and the ground select transistor are erased when the plurality of memory cells are erased.

7. The cell string of claim 6, wherein the string select transistor and the ground select transistor are programmed after the plurality of memory cells are erased.

8. The cell string of claim 7, wherein the string select transistor and the ground select transistor are programmed by hot carrier injection.

9. The cell string of claim 7, wherein the string select transistor and the ground select transistor are programmed by Fowler-Nordheim tunneling.

10. The cell string of claim 1, further comprising:
a first dummy memory cell connected between the string select transistor and the plurality of memory cells; and
a second dummy memory cell connected between the plurality of memory cells and the ground select transistor.

11. A cell string included in a memory cell array of a nonvolatile memory device, the cell string comprising:
a plurality of memory cells connected in series;
a plurality of string select transistors connected in series between a bitline and the plurality of memory cells, each string select transistor having a structure substantially the same as a structure of each memory cell; and
a plurality of ground select transistors connected in series between the plurality of memory cells and a common source line, each ground select transistor having a structure substantially the same as the structure of each memory cell.

12. The cell string of claim 11, wherein the plurality of string select transistors are connected to a single string select line.

13. The cell string of claim 11, wherein the plurality of ground select transistors are connected to a single ground select line.

14. A method of erasing a cell string included in a memory cell array of a nonvolatile memory device, the method comprising:
erasing a string select transistor, a plurality of memory cells and a ground select transistor that are connected in series; and
programming the string select transistor and the ground select transistor.

15. The method of claim 14, wherein the programming the string select transistor and the ground select transistor comprises:
programming the string select transistor; and
programming the ground select transistor after the string select transistor is programmed.

16. The method of claim 15, wherein programming the string select transistor comprises:
applying a first pass voltage to the plurality of memory cells and the ground select transistor;
applying a ground voltage to a common source line connected to the ground select transistor;
applying a drain program voltage to a bitline connected to the string select transistor; and
applying an incremental step pulse program voltage to the string select transistor.

17. The method of claim 16, wherein programming the string select transistor further comprises:
verifying whether the string select transistor is programmed; and
applying the ground voltage to the bitline if the string select transistor is programmed.

18. The method of claim 15, wherein programming the ground select transistor after the string select transistor is programmed comprises:
applying a first pass voltage to the plurality of memory cells;
applying a second pass voltage to the string select transistor, the second pass voltage having a voltage level higher than a voltage level of the first pass voltage;
applying a ground voltage to a common source line connected to the ground select transistor;
applying a drain program voltage to a bitline connected to the string select transistor; and
applying an incremental step pulse program voltage to the ground select transistor.

19. The method of claim 15, wherein programming the string select transistor comprises:
applying a pass voltage to the plurality of memory cells and the ground select transistor;
applying a ground voltage to a common source line connected to the ground select transistor and to a bitline connected to the string select transistor; and
applying a program voltage to the string select transistor.

20. The method of claim 14, wherein the programming the string select transistor and the ground select transistor comprises:
programming the ground select transistor; and
programming the string select transistor after the ground select transistor is programmed.
